(19) United States
(12) Patent Application Publication
(10) Pub. No.: US 2026/0278237 A1
(43) Pub. Date: Sep. 17, 2026

(54) VOLTAGE DOMAIN LAYOUT OPTIMIZATION AND COMPACTION

(71) Applicant: GLOBALFOUNDRIES U. S. Inc., Malta, NY (US)

(72) Inventor: Ivan Krasimirov KANEV, Sofia (BG)

(21) Appl. No.: 19/081,843

(22) Filed: Mar. 17, 2025

(51) Int. Cl. G06F 30/398; G06F 30/392

(52) U.S. Cl. CPC G06F 30/398; G06F 30/392

(57) ABSTRACT

Computer-aided semiconductor design may include parsing layout data and netlist data to respectively produce parsed layout data and parsed netlist data, determining, using the parsed layout data, a list of DTI objects and boundaries of voltage domains, and grouping devices in the parsed layout data according to the respective voltage domains to produce one or more voltage domain entries; for each voltage domain entry, extracting a first list corresponding to devices in parsed layout data that are in the voltage domain of the voltage domain entry from the parsed layout data, extracting a second list corresponding to devices in parsed netlist data that are in the voltage domain from the parsed netlist data, compares the first list of devices to the second list of devices, and determining that a compaction opportunity exists when a device exists in one of the first or second list but not in the other.

### FIELD OF THE DISCLOSURE

The present disclosure relates to integrated circuit design, and in particular to the layout of voltage domains and wells in integrated circuits such as may be performed by computer-aided design (CAD) tools, and with structures associated with said voltage domains and wells, such as isolation structures.

### BACKGROUND

An integrated circuit fabricated in a semiconductor die may include a plurality of voltage domains, each corresponding to one of a plurality of supply voltages.

Each voltage domain may be separated from the other voltage domains by an isolation structure, such as by Deep Trench Isolation (DTI). The isolation structures may potentially occupy a substantial amount of area on the semiconductor die.

Using CAD tools known in the art, such isolation structures may be created and placed between two voltage domains each associated with the same supply voltage, or between wells of the same doped material (e.g., between two p-wells or between two n-wells) that are each associated with the same supply voltage.

In order to improve some aspects of a layout design for an integrated circuit, such as parasitic capacitance, parasitic resistance, the effects of stress, substrate noise coupling, leakage current, and so on, designers may increase spacing between isolation structures or incorporate dummy structures. This may result in the creation of isolation structures that are unnecessary and that therefore waste area on the semiconductor die.

Because of the large number of isolation structures that may be incorporated into the design of an integrated circuit, it is impractical for a human being to identify such unnecessary isolations structures in the layout design.

Furthermore, the proximity of a device in the integrated circuit to an isolation structure may affect the operating characteristics of the device. For example, an isolation structure may introduce compressive stress on nearby regions of the semiconductor die, which compressive stresses may decrease charge mobility in devices in those regions, which would alter the performance of those devices. The magnitude of the effect may be based on the distance between the device and the isolation structure.

For some categories of circuits, the effect that a nearby isolation structure may have on the operating characteristics of components of the circuit may substantially affect the performance of the circuit. Examples of such circuits may include current mirrors, differential pairs, bandgap reference circuits, resistor and capacitor arrays (e.g., a precision R-2R ladder), operational amplifiers (especially the input stages thereof), switched-capacitor circuits, voltage-controlled oscillators, precision sense amplifiers, precision voltage dividers, analog multipliers, and the like.

These categories of circuits are referred to herein as DTI-sensitive circuits. A device in a DTI-sensitive circuit that may degrade the performance of the DTI-sensitive circuit as a result of the device's proximity to an isolation structure or the asymmetric disposition of isolation structures around the device is referred to herein as DTI-sensitive device. While such circuits and devices are referred to herein as “DTI-sensitive circuits” and “DTI-sensitive devices” for convenience, these terms may also refer to circuits and devices that are sensitive to the proximity or asymmetric disposition of other types of nearby isolation structures as well.

In such DTI-sensitive circuits, precision matching of components may be crucial to ensure that the structures perform their intended function accurately and reliably, particularly in analog and mixed-signal ICs where small variations can lead to significant performance degradation. The proximity of DTIs and other layout considerations play a critical role in achieving this precision. However, it is impractical for a human being to identify such DTI-sensitive circuits and the corresponding DTI-sensitive devices in the design of an integrated circuit of non-trivial complexity, and therefore impractical for a human being to determine whether proximity to DTIs is degrading the performance of such DTI-sensitive circuits in that design.

Accordingly, a need exists to control the placement of isolation structures on a semiconductor die in order to prevent area of the semiconductor die from being wasted and to minimize the deleterious effects of the isolation structures on the performance of DTI-sensitive circuits in the semiconductor die.

### SUMMARY

Embodiments of the present disclosure relate to computer-implemented tools for designing integrated circuits, and specifically to tools for optimizing the configuration and disposition of voltage domains, wells, and isolation structures on a semiconductor does.

In an embodiment, a method for performing semiconductor design is performed by a computer. The method comprises parsing layout data to produce parsed layout data, parsing netlist data to produce parsed netlist data, determining, using the parsed layout data, a list of DTI objects, determining, using the parsed layout data, boundaries of voltage domains, and grouping devices in the parsed layout data according to the respective voltage domains of the devices to produce one or more voltage domain entries. For each of the one or more voltage domain entries, the method extracts a first list of devices from the parsed layout data, the first list of devices corresponding to devices in parsed layout data that are in the voltage domain of the voltage domain entry, extracts a second list of devices from the parsed netlist data, the second list of devices corresponding to devices in parsed netlist data that are in the voltage domain of the voltage domain entry, compares the first list of devices to the second list of devices, and determines that a compaction opportunity exists when a device exists in the first list of devices that does not exist in the second list of devices, a device exists in the second list of devices that does not exist in the first list of devices, or both.

In an embodiment, a non-transient computer-readable medium comprises computer programming instructions which, when executed by a computer, cause the computer to perform steps of a process for semiconductor design. The steps comprise parsing layout data to produce parsed layout data, parsing netlist data to produce parsed netlist data, determining, using the parsed layout data, a list of DTI objects, determining, using the parsed layout data, boundaries of voltage domains, and grouping devices in the parsed layout data according to the respective voltage domains of the devices to produce one or more voltage domain entries. For each of the one or more voltage domain entries, the steps further comprise extracting a first list of devices from the parsed layout data, the first list of devices corresponding to devices in parsed layout data that are in the voltage domain of the voltage domain entry, extracting a second list of devices from the parsed netlist data, the second list of devices corresponding to devices in parsed netlist data that are in the voltage domain of the voltage domain entry, comparing the first list of devices to the second list of devices, and determining that a compaction opportunity exists when a device exists in the first list of devices that does not exist in the second list of devices, a device exists in the second list of devices that does not exist in the first list of devices, or both.

In embodiments, when the compaction opportunity exists, a DTI disposed between two devices in one of the one or more voltage domain entries is identified as an unnecessary DTI.

In embodiments, when the compaction opportunity exists, a revised layout data not having the unnecessary DTI is produced using the layout data.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 illustrates a disposition of isolation structures on an integrated circuit design.

FIG. 2 illustrates a disposition of isolation structures around a DTI-sensitive circuit in an integrated circuit design.

FIG. 3 illustrates a disposition of wells in an integrated circuit design.

FIG. 4 illustrates an Electronic Design Automation system according to an embodiment.

FIG. 5A illustrates a layout of an integrated circuit design.

FIG. 5B illustrates isolation structures on an integrated circuit design after performing optimization according to an embodiment.

FIG. 6A illustrates in more detail wasted area in the layout of FIG. 5A.

FIG. 6B illustrates in more detail locations where area was saved in the layout of FIG. 5B.

FIG. 7A illustrates a layout of an integrated circuit design.

FIG. 7B illustrates a layout of an integrated circuit design after performing optimization according to an embodiment.

FIG. 8 illustrates an integrated circuit design optimization process according to an embodiment.

FIG. 9 illustrates another integrated circuit design optimization process according to an embodiment.

FIG. 10 illustrates another integrated circuit design optimization process according to an embodiment.

FIG. 11 illustrates a process for performing voltage domain segmentation of an integrated circuit design, according to an embodiment.

FIG. 12 illustrates a process for verifying connection dependencies according to an embodiment.

FIG. 13 illustrates a process for performing a voltage domain comparison between a netlist and a layout of an integrated circuit design, according to an embodiment.

FIG. 14 illustrates a process for identifying Deep Trench Isolation (DTI) compaction opportunities for an integrated circuit design, according to an embodiment.

FIG. 15 illustrates a process for checking DTI proximity for DTI-sensitive devices in an integrated circuit design, according to an embodiment.

FIG. 16 illustrates a process for checking DTI symmetry, according to an embodiment.

FIG. 17 illustrates a process for grouping devices by wells, according to an embodiment.

FIG. 18 illustrates a process for checking well domain consistency in an integrated circuit design, according to an embodiment.

FIG. 19 illustrates a process for creating a list of well domain merging opportunities for an integrated circuit design, according to an embodiment.

FIG. 20 illustrates a process for identifying a DTI-sensitive device, according to an embodiment.

### DETAILED DESCRIPTION

Illustrative embodiments of the present disclosure will be described below in more detail with reference to the accompanying drawings. The inventive features may, however, be embodied in different forms and should not be construed as limited to the embodiments set forth herein. Rather, these embodiments are provided so that this disclosure will be thorough and complete, and will fully convey the scope of the present claims to those skilled in the art. Throughout the disclosure, like reference numerals refer to like parts throughout the various figures and embodiments.

It will be understood that, although the terms “first” and/or “second” may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element. Furthermore, in the following, a “set” of items refers to one or more of the items, and a “plurality” of items refers to two or more of the items.

The drawings are not necessarily to scale and, in some instances, proportions may have been exaggerated in order to clearly illustrate features of the embodiments.

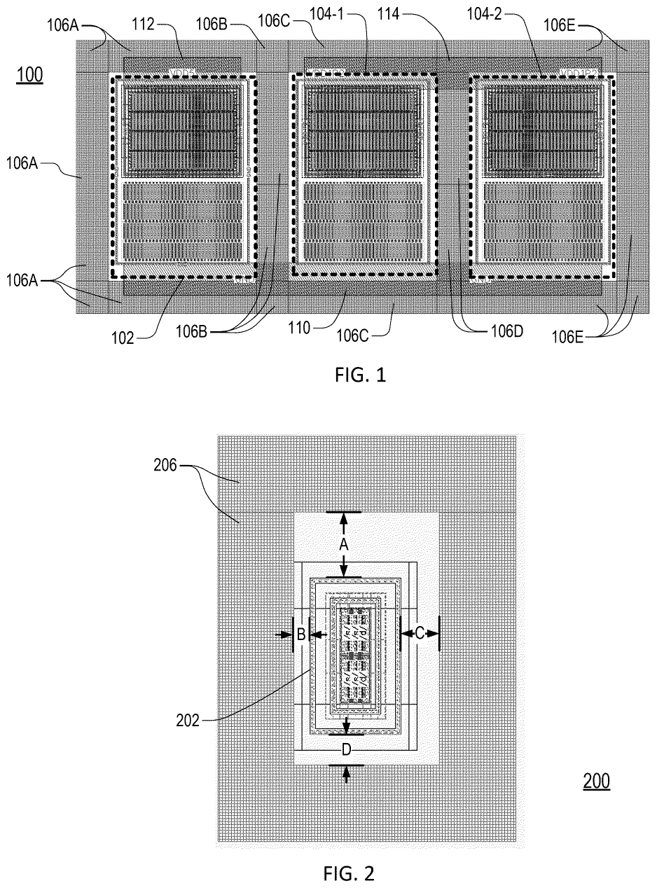

FIG. 1 illustrates a disposition of isolation structures on an integrated circuit design 100.

The integrated circuit design 100 includes a 5V voltage domain 102 coupled to a 5V supply trace 112 and a ground trace 110. The integrated circuit design 100 further includes a first 1.2V voltage domain 104-1 and a second 1.2V voltage domain 104-2 each coupled to a 1.2V supply trace 114 and the ground trace 110.

A plurality of isolation structures (here, DTIs) are disposed in the integrated circuit design 100. The isolation structures include a plurality of first DTIs 106A disposed around the 5V voltage domain 102, a plurality of second DTIs 106B disposed between the 5V voltage domain 102 and the first 1.2V voltage domain 104-1, a plurality of third DTIs 106C disposed around the first 1.2V voltage domain 104-1, a plurality of fourth DTIs 106D disposed between the first 1.2V voltage domain 104-1 and the second 1.2V voltage domain 104-2, and a plurality of fifth DTIs 106E disposed around the second 1.2V voltage domain 104-2.

Because the plurality of fourth DTIs 106D are disposed between two voltage domains corresponding to identical supply voltages, the plurality of fourth DTIs 106D are not necessary for voltage isolation. Embodiments of the present disclosure are configured to identify and, in some embodiments, eliminate such unnecessary isolation structures.

FIG. 2 illustrates disposition of isolation structures around a device 202 in an integrated circuit design 200. The device 202 may be a DTI-sensitive device in a DTI-sensitive circuit, and accordingly the device 202 may be sensitive to how far it is from nearby isolation structures, sensitive to a non-uniformity in how far it is from nearby isolation structures, or both. This sensitivity may exist even when the spacing between the isolation structures 206 and the device 202 is greater than a minimum spacing between circuits and isolation structures specified by a design rule.

A plurality of isolation structures 206 are disposed in proximity to the device 202. A first distance A, a second distance B, a third distance C, and a fourth distance D separate the device 202 from the plurality of isolation structures 206 on the upper, left, right, and bottom sides of the device 202, respectively.

As shown in FIG. 2, the first distance A has a different value than the fourth distance D, and the second distance B has a different value than the third distance C. As a result, the disposition of the isolation structures 206 is asymmetric which may affect the performance of the circuit including the device 202. Embodiments of the present disclosure are configured to identify and, in some embodiments, eliminate such asymmetric dispositions of isolation structures around DTI-sensitive devices.

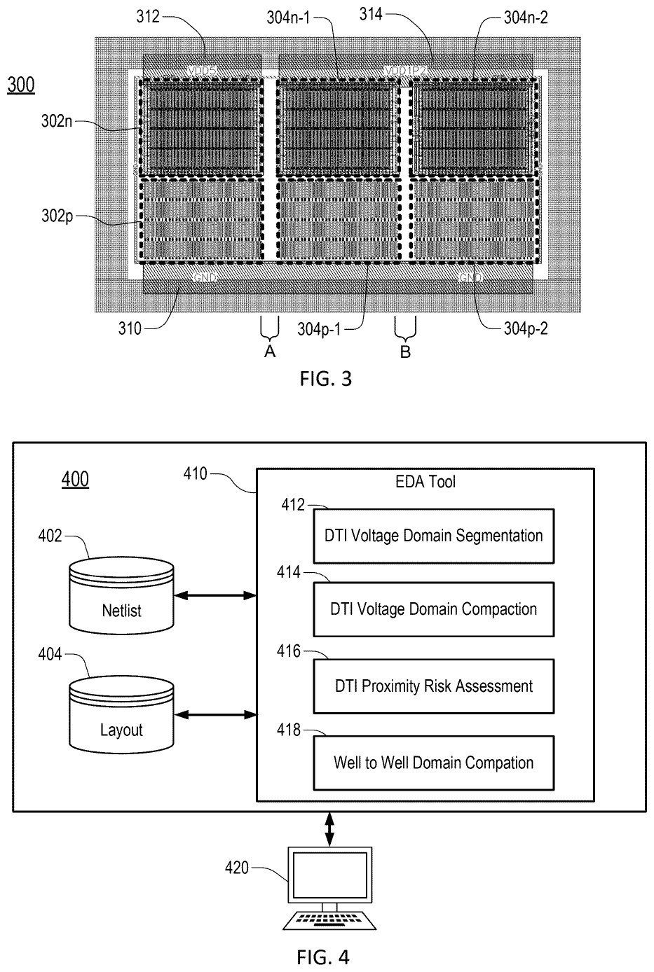

FIG. 3 illustrates a disposition of wells in an integrated circuit design 300. The wells include n-wells and p-wells for each of two voltage domains.

Specifically, the integrated circuit design 300 includes a 5V n-well 302 n, a 5V p-well 302p, a first 1.2V n-well 304n-1, a second 1.2V n-well 304n-2, a first 1.2V p-well 304p-1, and a second 1.2V p-well 304p-2. The 5V n-well 302n and 5V p-well 302p correspond to devices coupled between a 5V supply trace 312 and a ground trace 310. The first and second 1.2V n-wells 304n-1 and 304n-2 and the first and second 1.2V p-wells 304p-1 and 304 p-2 correspond to devices coupled between a 1.2V supply trace 314 and the ground trace 310.

As can be seen in FIG. 3, the 5V wells are separated from the 1.2V wells by a first gap A. Furthermore, the first 1.2V n-well 304n-1 and the first 1.2V p-well 304n-1 are each respectively separated from the second 1.2V n-well 304n-2 and the second 1.2V p-well 304n-2 by a second gap B.

However, because all of the 1.2V wells reside in the same 1.2V voltage domain, the separation provided by the second gap B is unnecessary. Embodiments of the present disclosure are configured to identify and, in some embodiments, eliminate such unnecessary gaps between wells that have the same type of doping (i.e., n or p) and that are in the same voltage domain.

FIG. 4 illustrates an Electronic Design Automation (EDA) system 400 according to an embodiment. The EDA system 400 may comprise one or more processors configured to provide an EDA tool 410 by executing computer programming instructions stored on a non-transitory computer-readable medium. Although the EDA system 400 is represented by a single box, the EDA system 400 may be provided by a plurality of devices (including, for example, one or more workstations, one or more servers, one or more network-attached storage devices, one or more database servers, and the like, or combinations thereof) in communication with each other.

The EDA system 400 includes a netlist database 402 and a layout database 404 that provide information about an integrated circuit design to an EDA tool 410. The EDA Tools 410 may also modify the information about the integrated circuit design in the netlist database 402, in the layout database 404, or in both.

The EDA system 400 may receive inputs (such as commands and their associated parameters) and provide outputs (such as depictions of a design, information about a design, and so on) to a user interface device 420. The user interface device may provide a Graphical User Interface (GUI) through which a human being may interact with the EDA system 400.

The embodiment of the EDA tool 410 shown in FIG. 4 includes, along with other components, a DTI voltage domain segmentation component 412, a DTI voltage domain compaction component 414, a DTI Proximity Risk Assessment component 416, and a Well to Well Domain Compaction component 418. These components are described in more detail below.

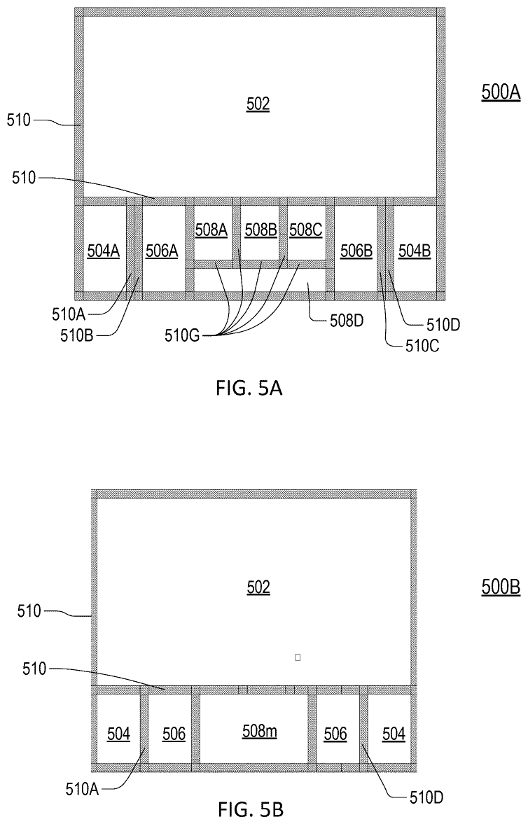

FIG. 5A illustrates a layout 500A of an integrated circuit design such as might be processed by an embodiment. The layout includes a plurality of voltage domains and a plurality of isolation structures (here, DTIs).

The layout 500A includes a voltage-one (V1) domain 502 corresponding to a first supply voltage, first and second voltage-two (V2) domains 504A and 504B corresponding to a second supply voltage, first and second voltage-three (V3) domains 506A and 506B corresponding to a third supply voltage, and first through fourth voltage-four (V4) domains 508A through 508D corresponding to a fourth supply voltage. Each voltage domain is separated from the other voltages by at least one DTI 510.

However, the first V2 voltage domain 504A is separated from the first V3 voltage domain 506A by first and second DTIs 510A and 510B interposed sequentially therebetween, and the second V2 voltage domain 504B is separated from the second V3 voltage domain 506B by third and fourth DTIs 510C and 510D interposed sequentially therebetween. As only one interposed DTI is needed to separate a voltage domain from another voltage domain, one of the first and second DTIs 510A and 510B and one of the third and fourth DTIs 510C and 510D are unnecessary.

Also, each of the first through fourth V4 domains is separated from at least one of the other first through fourth V4 domains by at least one of a plurality of fifth DTIs 510G. Because all of the first through fourth V4 domains 508A through 508D correspond to the same supply voltage, the plurality of fifth DTIs 510G are unnecessary.

FIG. 5B illustrates an optimized layout 500B including isolation structures of an integrated circuit design after performing optimization according to an embodiment. In particular, FIG. 5B illustrates the effect of removing unnecessary DTIs from the integrated circuit design shown in FIG. 5A.

As shown in the optimized layout 500B of FIG. 5B, in the integrated circuit design, DTIs 510B and 510C of FIG. 5A have been removed as unnecessary. Also, the plurality of DTIs 510G that were interposed among the first through fourth V4 domains 508A through 508D of FIG. 5A have been removed as unnecessary, resulting in the first through fourth V4 domains 508A through 508D of FIG. 5A being consolidated into a single V4 domains 508m.

As can be seen in FIGS. 5A and 5B, the elimination of unnecessary DTIs from the integrated circuit design results in a significant saving of die area.

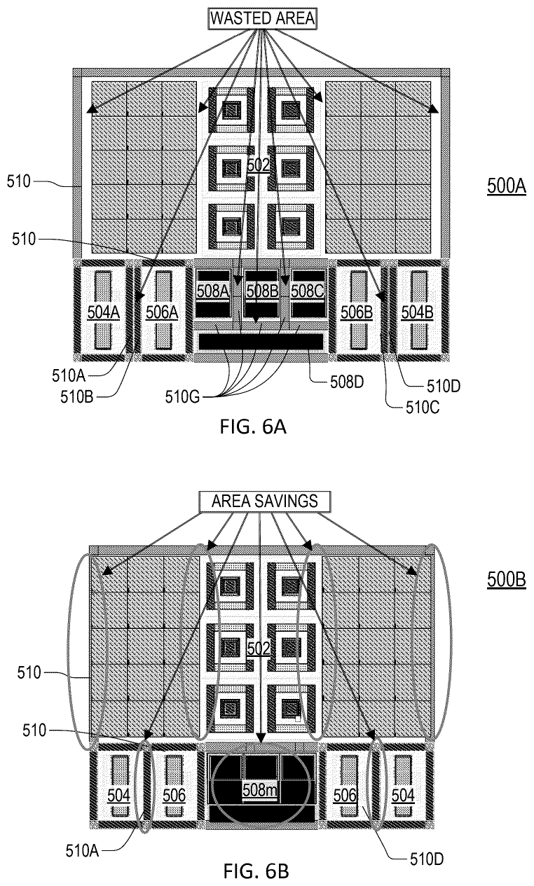

FIG. 6A illustrates in more detail wasted area in the layout of FIG. 5A. In addition to the area wasted by unnecessary DTIs as shown in FIG. 5A, FIG. 6A shows that area was also wasted in the V1 domain 502 because the dimensions of the V1 domain 502 were constrained according to the dimension of the other voltage domains, and not just by the dimensions of the components included in the V1 domain 502.

FIG. 6B illustrates in more detail locations where area was saved in the layout of FIG. 5B, including where area was saved internal to the V1 domain 502.

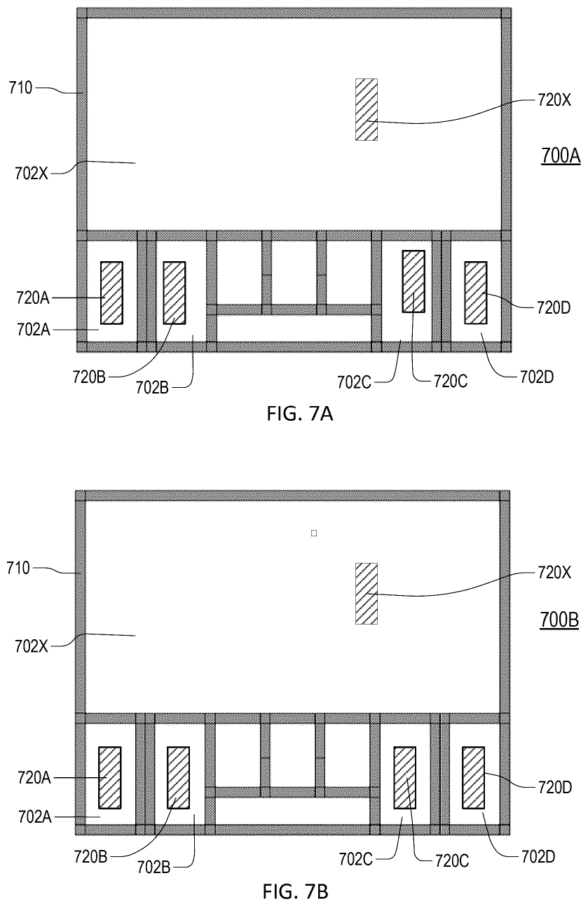

FIG. 7A illustrates a layout 700A of an integrated circuit design including DTI-sensitive devices having asymmetric proximity to DTIs.

The layout 700A includes first through fourth voltage regions 702A through 702D, each encompassed by a plurality of DTIs 710. The first through fourth voltage regions 702A through 702D respectively include first through fourth DTI-sensitive devices 720A through 720D. A fifth voltage region 702X includes a fifth DTI-sensitive device 720X.

The performance of each of the first through fourth DTI-sensitive devices 720A through 720D is affected by the symmetry of the proximity of the DTIs surrounding the voltage region it is part of.

As can be seen in FIG. 7A, the disposition of the DTIs around the second DTI-sensitive device 720B and the third DTI-sensitive device 720C are asymmetric. This asymmetry may negatively impact the performance of respective DTI-sensitive circuits that include the second and third DTI-sensitive devices 720B and 720C.

FIG. 7B illustrates a layout 700B of on an integrated circuit design of FIG. 7A after performing optimization according to an embodiment. In the layout 700B, the second and third DTI-sensitive devices 720B and 720C have been relocated so that all of the first through fourth DTI-sensitive devices 720A though 720D have symmetric proximity to their surrounding DTIs 710.

The relocation of the second and third DTI-sensitive devices 720B and 720C shown in FIG. 7B may be performed by an embodiment automatically, or in another embodiment may be performed after confirmation of the new location by a user of the embodiment. In another embodiment, one or more relocation options for the second and third DTI-sensitive devices 720B and 720C shown in FIG. 7B may be provided to a user of the system as a suggestion.

In the embodiment of FIG. 7B, symmetric proximity means that the DTI to the left of a DTI-sensitive device is essentially displaced by the same distance from the DTI-sensitive device as the DTI to the right, and the DTI above the DTI-sensitive device is essentially displaced by the same distance from the DTI-sensitive device as the DTI below it, but embodiments are not limited thereto.

In another embodiment, symmetric proximity may mean that the DTIs above, below, left, and right of a DTI-sensitive device are all displaced at essentially the same distance from the sensitive circuit.

In another embodiment, DTIs that are displaced more than a threshold distance from the DTI-sensitive device are not evaluated for symmetry when the DTI on the opposite side of the sensitive circuit is also displaced by more than the threshold distance. For example, in FIGS. 7A and 7B, the fifth DTI-sensitive device 720X is sufficiently distant from the closest of the DTIs 710 that the asymmetry of the distances to the DTIs does not noticeably impact the performance of the fifth DTI-sensitive device 720X, and accordingly the fifth DTI-sensitive device 720X was not relocated by the optimization process.

The need for symmetry in the distances to DTIs around a DTI-sensitive device and the threshold distances beyond which the asymmetry of the DTIs does not have a substantial negative effect on the performance of the sensitive circuit may vary according to the type or the intended use of the DTI-sensitive circuit incorporating the DTI-sensitive device.

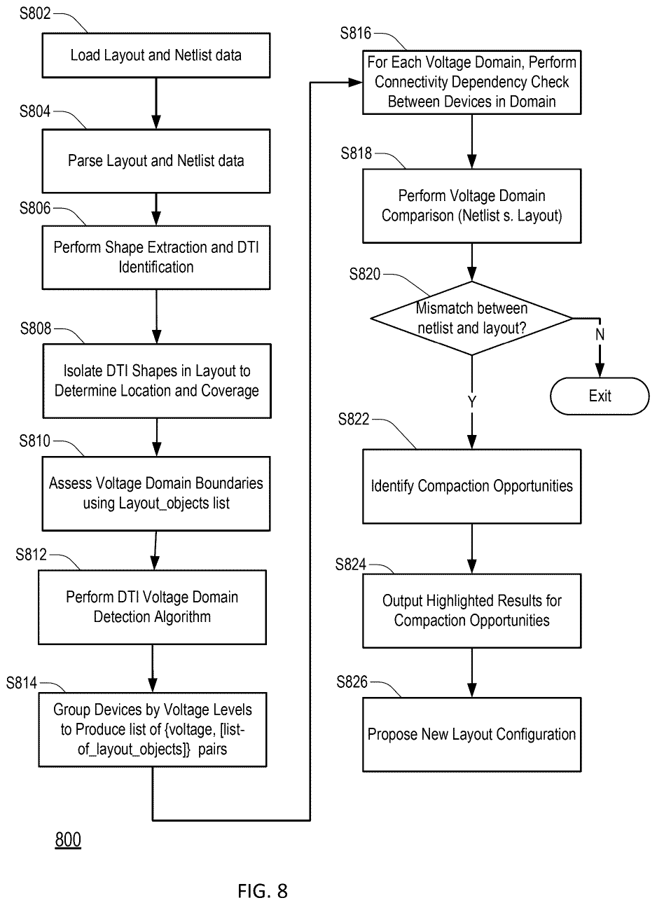

FIG. 8 illustrates an integrated circuit design optimization process 800 according to an embodiment. The process 800 identifies and optionally eliminates unnecessary isolation structures (here, DTIs) from a design of an integrated circuit.

At step S802, the process loads layout data and netlist data for a design to be optimized. The layout data may be in, for example, Graphic Design System II (GDSII) format, Open Artwork System Interchange Standard (OASIS) format, or the like, or combinations thereof. The netlist files may be in, for example, Simulation Program with Integrated Circuit Emphasis (SPICE) format, Circuit Design Language (CDL), or combinations thereof.

At step S804, the process 800 parses the layout data and the netlist data.

The parsed layout data may comprise, to give an example in Python, a “layout_objects” list of dictionary entries, each dictionary entry including, among other possible items, a “type” key having a value of a type of a layout object (such as “device” or “dti”), a “name” key having a value of a name of a layout object, a “voltage” key having a value of a supply voltage associated with the object (or “none” in the case of unpowered objects like DTIs), and a “coordinates” key having a value including one or more pairs of X and Y coordinates in the layout of the object.

The parsed netlist data may comprise, to give an example in Python, a “netlist_voltage_domains” dictionary comprising a voltage value and a list of device names of devices in a domain having that voltage value.

A person of ordinary skill in the related arts would be able to determine how to produce an algorithm and corresponding programming instructions to perform step S804 as described above.

At step S806, the process 800 extracts DTI regions from the parsed layout data by collecting all the objects of type “dti” in the parsed layout data into a list of DTI objects.

At step S808, using the list of DTI objects, the process 800 determines the shape and location of the DTIs in the design and the coverage provided thereby. First, the process 800 extracts the coordinates of DTI objects from the parsed layout data. This involves identifying the specific layout objects that are classified as DTIs and retrieving their spatial coordinates. Then the process 800 analyzes these coordinates to calculate the geometric properties of each DTI. This includes determining the boundaries of the DTIs, which are defined by the respective minimum and maximum x and y coordinates of the DTIs. By calculating these boundaries, the process 800 determines the coverage area of each DTI and how they are positioned within the layout. Additionally, the process 800 may assess the spatial relationships between DTIs and other layout objects, such as devices and voltage domains. A person of ordinary skill in the related arts would be able to determine how to produce an algorithm and corresponding programming instructions to perform step S804 as described above.

At step S810, using the parsed layout data, the process 800 determines the boundaries of voltage domains within the design. First, the process 800 analyzes the spatial coordinates and connectivity of devices within the layout; which includes identifying the specific layout objects that are classified as devices and retrieving their spatial coordinates and voltage values. Next, the process 800 groups these devices based on their voltage values and spatial proximity. By doing this, the process 800 can delineate the boundaries of each voltage domain accurately. This grouping process involves creating entries for each unique voltage domain, where each entry includes a list of devices that operate at the same voltage and are spatially close to each other. Additionally, the process 800 may assess the connectivity between devices within each voltage domain to ensure that they are properly linked according to the netlist. A person of ordinary skill in the related arts would be able to determine how to produce an algorithm and corresponding programming instructions to perform step S808.

At step S812, using the determined voltage domains and the shape, location, and coverage information determined for the DTIs, the process 800 performs DTI voltage domain detection. Specifically, the process 800 groups devices by their voltage values, creating entries for each unique voltage domain. In cases where multiple domains share the same supply voltage, the process 800 ensures that devices are grouped correctly based on their spatial relationships and connectivity. This prevents incorrect merging of distinct voltage domains and maintains the integrity of the layout.

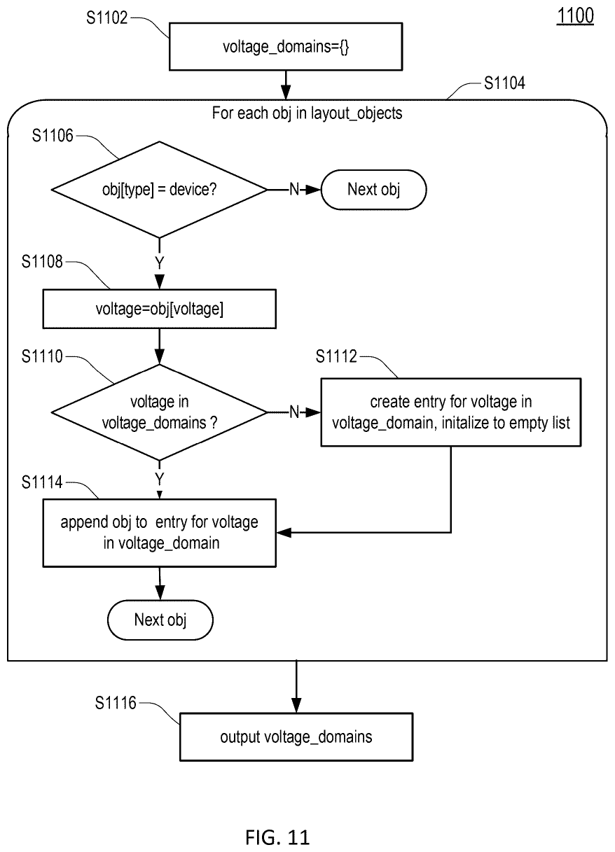

At step S814, using the parsed layout data, the process 800 groups devices in the layout according to the voltage domain they are in, including using the spatial relationships and connectivity information of the devices to ensure that incorrect merging of separate voltage domains having the same supply voltage does not occur. The grouped devices may be represented, for example, as a Python dictionary having entries each including a “voltage” key having a value of a supply voltage for a domain and a list of objects in a voltage domain corresponding to that supply voltage. An example algorithm for grouping devices in the layout according to voltage domain is disclosed in FIG. 11 and the accompanying text, but embodiments are not limited thereto.

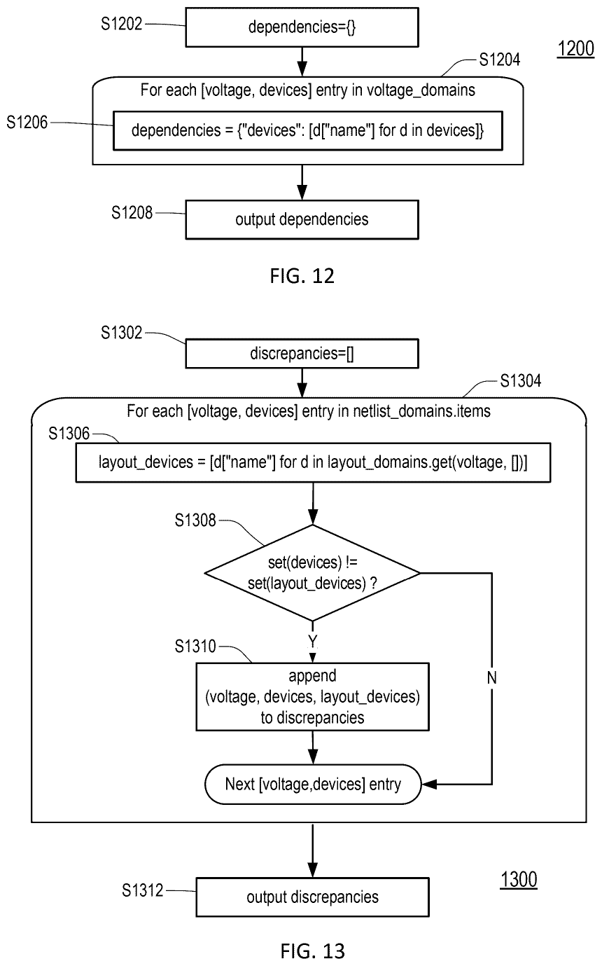

At step S816, the process 800 performs, for each voltage domain, a connectivity dependency check for the devices in that domain. The connectivity dependency check output may be represented, for example, as a Python dictionary having entries each including a “voltage” key having a value of a supply voltage for a domain and a list of names of devices in a voltage domain corresponding to that supply voltage. An example algorithm for performing such a connectivity dependency check is disclosed in FIG. 12 and the accompanying text, but embodiments are not limited thereto.

Specifically, the connectivity of devices within each voltage domain is checked to ensure that they are properly linked as specified in the netlist. Also, the presence of any discrepancies between the devices listed in the netlist and those in the layout for each voltage domain is also checked.

To perform these checks, the process 800 creates a ‘dependencies’ dictionary, where each entry includes a voltage key and a list of device names that are supposed to be connected within that voltage domain. The layout data is parsed to extract the connectivity information of devices, which is then compared against the netlist data. For each voltage domain, the devices listed in the layout are compared with the devices listed in the netlist to ensure they match. Any discrepancies, such as devices present in one list but not the other, are flagged for further analysis.

By performing this connectivity dependency check, we ensure that the layout accurately reflects the intended design as specified in the netlist, and we identify potential optimization opportunities by highlighting any inconsistencies.”

At step S818 the process 800, using the parsed netlist data from step S804 and the connectivity dependency check output from step S816, checks for discrepancies between the netlist and the layout. The check for discrepancies produces a list of entries each indicating a voltage, a set of netlist devices, and a set of layout devices where the set of netlist devices was not equal to the set of layout devices. An example algorithm for performing such a connectivity dependency check is disclosed in FIG. 13 and the accompanying text, but embodiments are not limited thereto.

At step S820, the process 800 checks whether there was a mismatch between devices in a netlist domain and devices in a corresponding layout domain, that is, whether the output of step S818 was not an empty list. If so, this indicates that there may be an opportunity to compact the layout, and the process 800 proceeds to S822. Otherwise the process 800 exits.

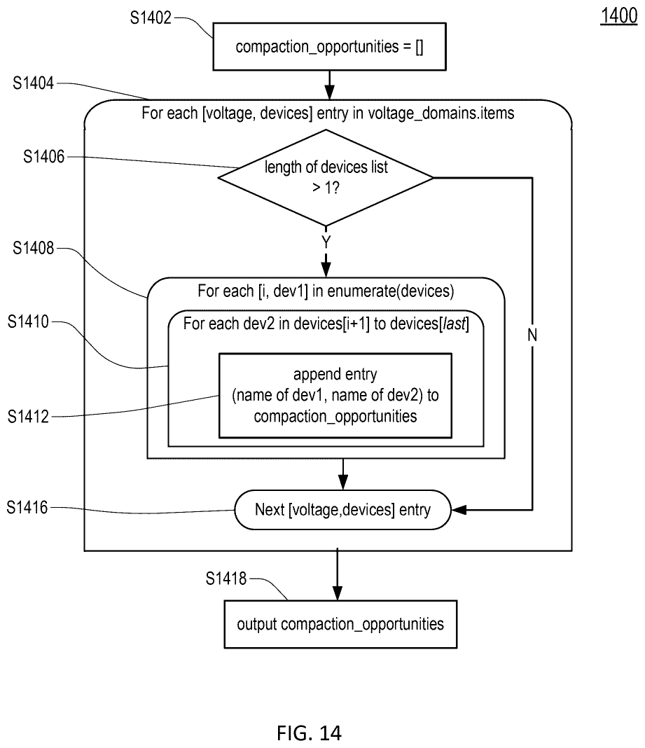

At step S822, the process 800 identifies compaction opportunities in the layout. The identified compaction opportunities may be represented as a list of tuples, each tuple including a pair of device names; the compaction opportunity is a DTI disposed between the two devices. An example algorithm for identifying compaction opportunities is disclosed in FIG. 14 and the accompanying text, but embodiments are not limited thereto.

Upon determining the compaction opportunities, the process 800 may perform step S824, step S826, or both.

At step S824, the process 800 may output the compaction opportunities by indicating a DTI disposed between the pairs of devices in the identified compaction opportunities. This may include presenting a display comprised of text corresponding to the DTI in the layout data, highlighting text corresponding to the DTI in a listing of the layout data, highlighting a graphical representation of the DTI in a GUI displaying the layout, or combinations thereof.

At step S826, the process 800 may generate and output a new layout in which a DTI disposed between two devices in an entry in the identified compaction opportunities has been removed. The process 800 may produce the new layout by removing just one such DTI, by removing all such DTIs corresponding to the entries in the identified compaction opportunities, or by removing DTIs corresponding to selected entries in the identified compaction opportunities, wherein the selection may be performed by a user. A person of ordinary skill in the related arts would be able to determine how to produce an algorithm and corresponding programming instructions to perform step S826.

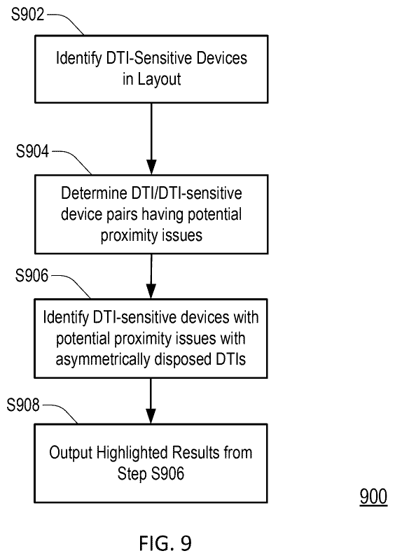

FIG. 9 illustrates another integrated circuit design optimization process 900 according to an embodiment. The process 900 identifies and optionally corrects asymmetric dispositions of DTIs around DTI-sensitive devices. The process 900 may be performed in concert with all or some of the steps of the process 800 of FIG. 8.

At step S902, the process 900, using the layout data described with respect to step S802 of FIG. 8, identifies DTI-sensitive devices in a layout of an integrated circuit design. The DTI-sensitive devices may be identified using a sensitivity characteristic expressed in the layout data for that device. A DTI-sensitive device may be identified by having a sensitivity of “high,” for example.

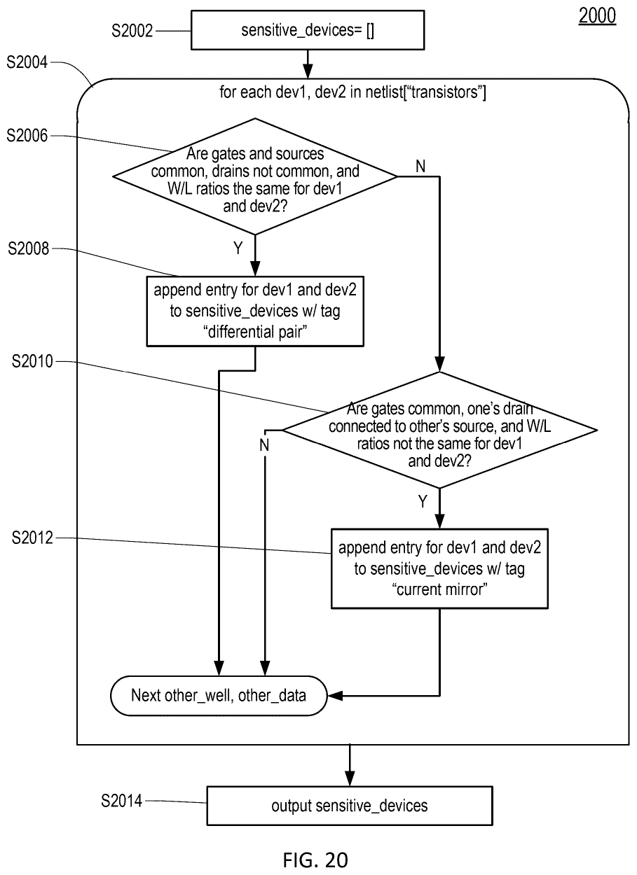

In some cases, the “sensitivity” characteristic may be determined by one or more DTI-sensitive devices detection algorithms. An example of such an algorithms is disclosed in FIG. 20 and the associated text, but embodiments are not limited thereto.

In some cases, the “sensitivity” characteristic may be derived from a characteristic of the device in a cell library that includes the device; for example, a cell corresponding to a differential amplifier circuit in a cell library may include two or more devices operating as a differential input stage that are each assigned a high sensitivity value. In other cases, the “sensitivity” characteristic may be determined by a type of the device; for example, all diode-connected Field Effect Transistors FETs), which typically find uses in DTI-sensitive circuits such as current mirrors, may be assigned a high sensitivity value. However, embodiments are not limited thereto.

The output of step S902 may be represented as a list of layout objects identified as being DTI-sensitive devices.

In step S904 the process 900, using information on DTIs such as that produced in step S808 of process 800 of FIG. 8 and using the list of layout objects identified as being DTI-sensitive devices from step S902, identifies DTI-sensitive devices that may suffer performance degradation because of the proximity or asymmetric disposition of nearby DTIs.

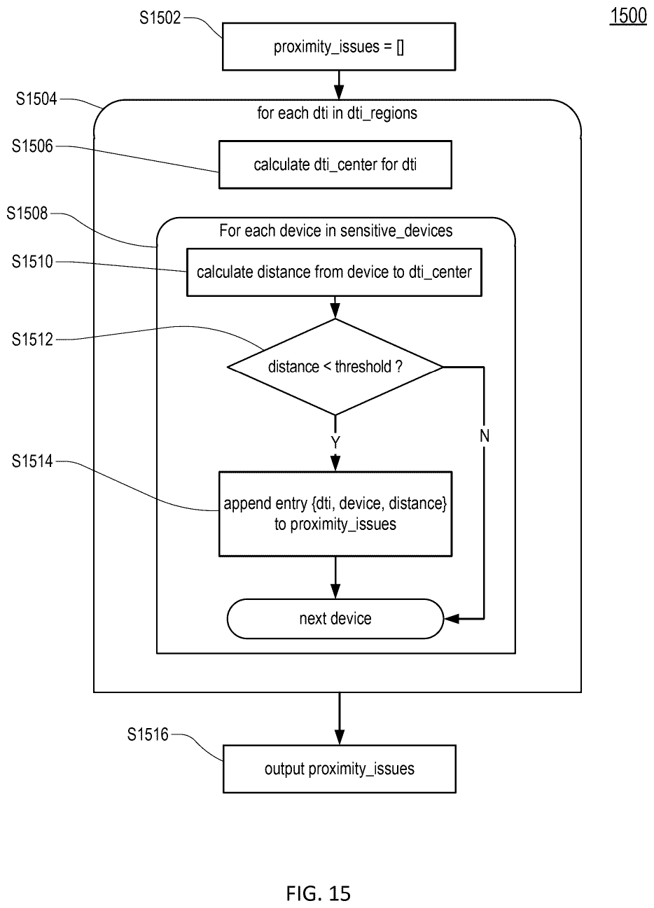

The output of step S904 may be a “proximity issues” list of triples, each triple including an indication of a DTI, an indication of a DTI-sensitive device, and a distance between the DTI and the DTI-sensitive device. An algorithm for performing step S904 is disclosed in FIG. 15 and the associated text, but embodiments are not limited thereto.

In other embodiments, the list of pairings of DTIs and DTI-sensitive devices may be reduced or may be originally created using only DTI/DTI-sensitive device pairs that are in a same region of the layout. Such a reduced list may be produced using techniques widely known in the art.

In step S906 the process 900, using the “proximity issues” list from step S904, identifies DTI-sensitive devices with potential proximity issues for which the nearby DTIs are asymmetrically disposed.

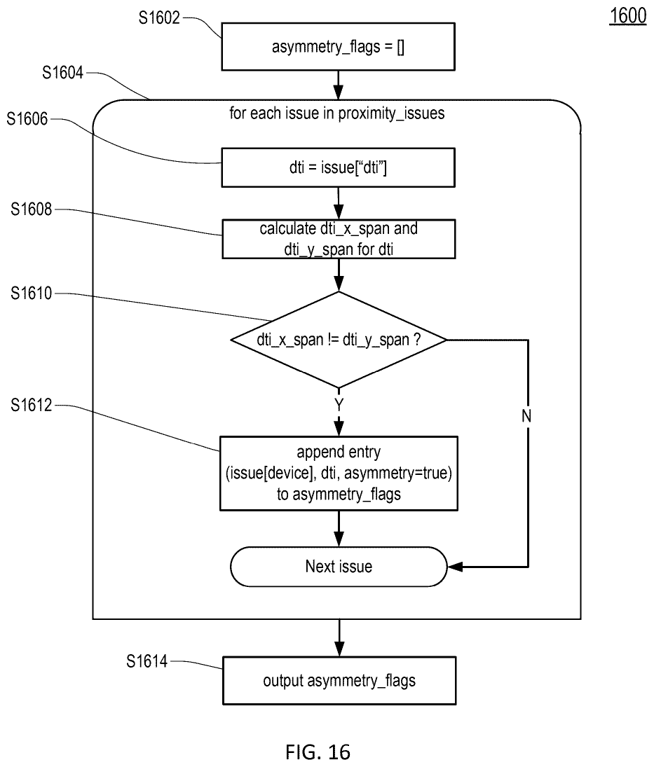

The output of step S906 may be an “asymmetry flag” list of triples, each triple including an indication of a DTI-sensitive device, an indication of a DTI, and a flag indicating that the DTI is asymmetrically disposed near the DTI-sensitive device. An algorithm for performing step S904 is disclosed in FIG. 16 and the associated text, but embodiments are not limited thereto.

At step S908, the process 800 may output the “asymmetry flag” list to a user by indicating one or more DTIs in the “asymmetry flag” list. This may include presenting a display comprised of text corresponding to the DTIs in the layout data, highlighting text corresponding to the DTIs in a listing of the layout data, highlighting a graphical representation of the DTIs in a GUI displaying the layout, or combinations thereof.

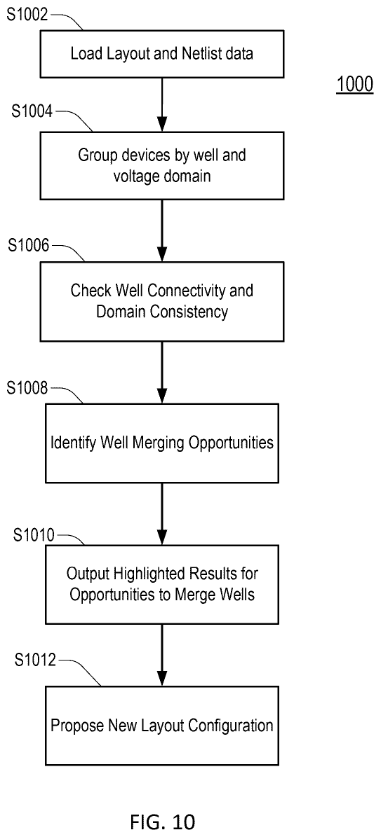

FIG. 10 illustrates another integrated circuit design optimization process 1000 according to an embodiment. The process identifies unnecessary isolation structures between well domains of the integrated circuit design.

At step S1002, the process 1000 loads layout data and netlist data for a design to be optimized, as described for step S802 of process 800 of FIG. 8.

At step S1004, the process 1000, using the layout data from step S1002, groups devices by well and layout domain. The output of step S1004 may be represented by, for example, a Python dictionary wherein each entry includes an identifier of a well, a voltage corresponding to the identified well, and a list of devices in the well.

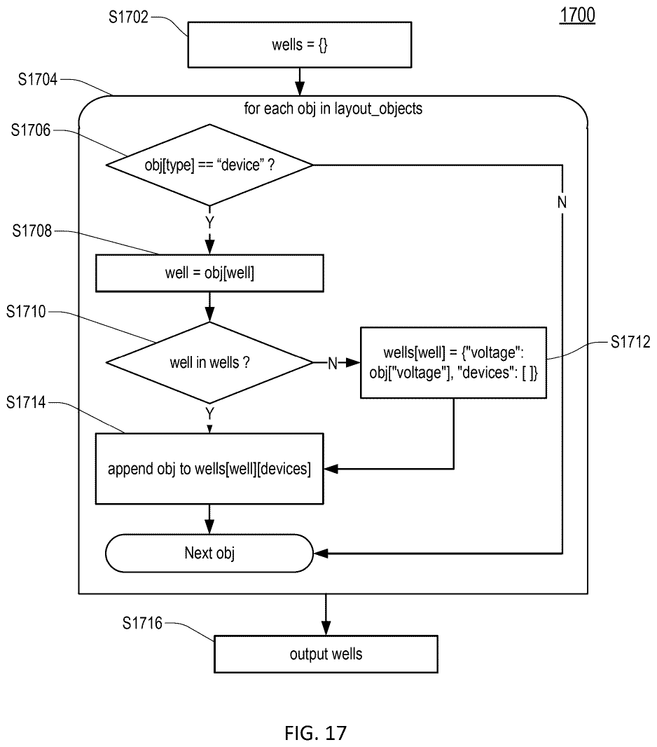

An algorithm for performing step S1004 is disclosed in FIG. 17 and the associated text, but embodiments are not limited thereto.

At step S1006, the process 1000, using the output of step S1004, performs a well and domain connectivity and consistency check. The output of step S1006 indicates pairs of wells having the same corresponding supply voltage, and may be represented by, for example, a Python list wherein each entry includes an identifier of a source well, an identifier of a target well, and a voltage corresponding to both wells. The output of step S1006 may be referred to as “domain consistency issues.”

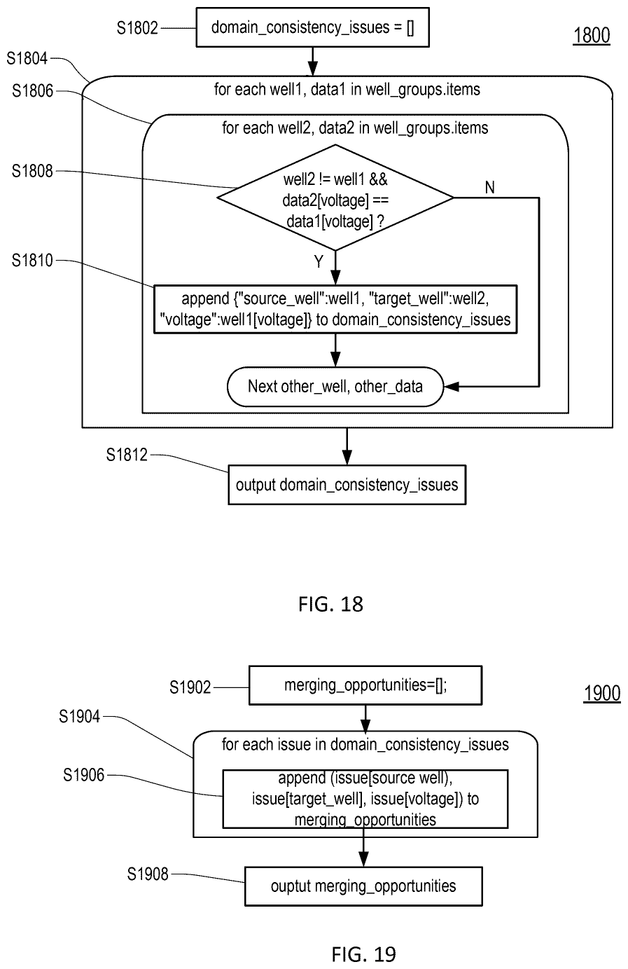

An algorithm for performing step S1006 is disclosed in FIG. 18 and the associated text, but embodiments are not limited thereto.

At step S1008, the process 1000, using the output of step S1006, identifies opportunities to merge wells. The output of step S1006 indicates pairs of wells having the same corresponding supply voltage that may be merged, and may be represented by, for example, a Python list wherein each entry includes an identifier of a source well, an identifier of a target well, and a voltage corresponding to both wells.

An algorithm for performing step S1008 is disclosed in FIG. 19 and the associated text, but embodiments are not limited thereto.

Upon determining the opportunities to merge wells, the process 1000 may perform step S1010, step S1012, or both.

At S1010, the process 1000 may output the opportunities to merge wells by indicating the pairs of wells in the output from step S1008. This may include presenting a display comprised of text corresponding to the pairs of wells in the layout data, highlighting text corresponding to the pairs of wells in a listing of the layout data, highlighting graphical representations of the pairs of wells in a GUI displaying the layout, or combinations thereof.

At S1012, the process 1000 may generate and output a new layout in which one or more pairs of wells indicated in the output from step S1008 are merged into a single well. The process 800 may produce the new layout by merging just one such pair of wells, by merging all such pair of wells, or by merging all such pair of wells corresponding to selected entries in the identified opportunities to merge wells, wherein the selection may be performed by a user. A person of ordinary skill in the related arts would be able to determine how to produce an algorithm and corresponding programming instructions to perform step S826.

FIGS. 11 through 21 are flowcharts illustrating algorithms according to embodiments. In FIGS. 11 through 21, “for each” loops may be visually represented by “bread load” shapes having the iteration parameters of the loop presented in text at the top and the operations incorporated into the body of the loop presented as a flowchart within the “bread loaf.” When not otherwise indicated, reaching the end of a flowchart in the “bread loaf” results in the next iteration of the loop to be performed or the end of the loop, depending on the progress of the “for each” loop through the data structure being iterated through.

The code shown in FIGS. 11 through 21 is “Python-like” but, for easier comprehension, does not strictly adhere to the syntax of the Python language.

FIG. 11 illustrates a process 1100 for performing, using a list of layout objects, voltage domain segmentation of an integrated circuit design, according to an embodiment.

At step S1102, the process 1100 sets the voltage_domains variable to an empty dictionary.

At step S1104, the process 1100 iterates through the objects in the list of layout objects.

At step S1106, the process 1100 determines whether the object being processed is a device. If it is (Y), the process 1100 proceeds to step S1108; if not (N) the process 1100 proceeds to the next iteration of the loop of step S1104.

At step S1108, the process 1100 determines a voltage of the object being processed, which here is an entry in the object's data structure.

At step S1110, the process 1100 determines whether an entry for the voltage of the object is present in the voltage_domains dictionary. If so (Y), the process 1100 proceeds to step S1114; if not (N) the process 1100 proceeds to step S1112.

At step S1112, the process 1100 creates an entry for the voltage of the object in the voltage_domains dictionary. The entry include the voltage as a key and also includes an initially-empty list that will be used to store objects in the voltage domain corresponding to the voltage.

At step S1114, the process 1100 appends the object to a list of objects in an entry of the voltage_domains dictionary corresponding to the voltage. The process 1100 then proceeds to the next iteration of the loop of step S1104.

In response to the loop of step S1104 having iterated through all the objects in the layout_objects list, at step S1116 the process 1100 outputs the voltage_domains dictionary.

FIG. 12 illustrates a process 1200 for verifying, using a voltage_domains dictionary such as may be produced by the process 1100 of FIG. 11, connection dependencies according to an embodiment.

At step S1202, the process 1200 sets the dependencies variable to an empty dictionary.

At step S1204, the process 1200 iterates through entries in the voltage_domains dictionary, where each entry includes a voltage and a list of devices corresponding to that voltage.

At step S1206, for each entry in the voltage_domains dictionary, the process 1200 creates an entry in the dependencies dictionary, the entry having a key with a value “devices” and having a list comprised of the names of all the devices in the list of devices in the entry.

At step S1208, after the loop of step S1204 has iterated through all the entries in voltage_domains, the process 1200 outputs the dependencies dictionary.

FIG. 13 illustrates a process 1300 for performing a voltage domain comparison between a netlist and a layout of an integrated circuit design, according to an embodiment.

At step S1302, the process 1300 sets a discrepancies variable to an empty list.

At step S1304, the process 1300 iterates through entries in an items entry of a netlist_domains data structure, where each entry includes a voltage of a voltage domain and a list of names of devices corresponding to that voltage domain.

At step S1306, the process 1300 creates a layout_devices list comprised of name of devices in a layout domain having the same voltage as the current entry being processed by the loop of step S1304.

At step S1306, the process 1300 determines whether the names of the devices in the layout_domain entry of step S1306 are different from the names of the devices in the netlist_domains entry being processed by the loop of step S1304; that is, whether the netlist domain and the corresponding layout domain having the same voltage do not contain the same devices.

When the layout domain and the netlist domain have at least one different device (that is, a device in the layout domain that is not in the netlist domain, or a device in the netlist domain that is not in the layout domain), the process 1300 proceeds to step S1310; otherwise the process 1300 proceeds to the next iteration of the loop of step S1304.

At steps S1310, the process 1300 appends an entry to the discrepancies list, the entry corresponding to a netlist/layout domain pair having the same voltage but not the same devices, and comprising an indication of the voltage, a list of device names of devices in the netlist domain, and a list of device names of devices in the layout domain.

At step S1312, after the loop of step S1304 has iterated through all the entries in voltage_domains, the process 1300 outputs the discrepancies list.

FIG. 14 illustrates a process 1400 for identifying Deep Trench Isolation (DTI) compaction opportunities for an integrated circuit design, according to an embodiment.

At step S1402, the process 1400 sets a compaction_opportunities variable to an empty list.

At step S1404, the process 1400 iterates through entries in an items entry of a voltage_domains data structure, where each entry includes a voltage of a voltage domain and a list of names of devices corresponding to that voltage domain.

At step S1406, the process 1400 determines whether there is more than one entry in the list of devices for the entry currently being processed by the loop of step S1404. If so, the process 1400 proceeds to step S1408; otherwise the process 1400 proceeds to the next iteration of the loop of step S1404.

At step S1408, the process 1400 iterates through the list of devices for the entry currently being processed by the loop of step S1404, assigning an index variable i to indicate the position in the list of devices and assigning the device at that index to variable dev1.

At step S1410, the process 1400 iterates through a tail of the list of devices for the entry currently being processed by the loop of step S1404, with the tail starting at the device in the list at index i+1. The device corresponding to the current iteration of the loop of step S1410 is assigned to variable dev2.

At step S1412, the process 1400 appends an entry comprising the name of the device assigned to dev1 and the name of the device assigned to dev2 to the compaction_opportunities list.

When the loops of steps S1410, S1408, and S1404 have performed all their iterations, the process 1400 outputs the compaction_opportunities list.

FIG. 15 illustrates a process 1500 for checking DTI proximity for DTI-sensitive devices in an integrated circuit design, according to an embodiment.

At step S1502, the process 1500 sets a proximity_issues variable to an empty list.

At step S1504, the process 1500 iterates through each DTI in a dti_regions variable that corresponds to a list of DTIs.

At step S1506, the process 1500 determines a center coordinate for the DTI currently being processed. The center coordinate may correspond to an average of first and second x coordinates of the DTI and an average of first and second Y coordinates of the DTI.

At step S1508, process 1500 iterates through a list of DTI-sensitive devices.

At step S1510, the process 1500 calculates a distance from the DTI-sensitive device currently being processed and the center coordinate of the DTI currently being processed. The calculated distance may be a Euclidean distance.

At step S1512, the process 1500 determines whether the calculated distance is less than a threshold value. If the calculated distance is less than the threshold, the process 1500 proceeds to step S1514; otherwise, the process 1500 proceeds to the next iteration of the loop of step S1508.

At step S1514, the process 1500 appends an entry corresponding to the current DTI and DTI-sensitive device currently being processed to the proximity_issues list. The entry comprises an indication of the DTI currently being processed, the DTI-sensitive device currently being processed, and the calculated distance between them.

At step S1516, when the loops of steps S1508 and S1504 have performed all their iterations, the process 1500 outputs the proximity_issues list.

FIG. 16 illustrates a process 1600 for checking, using a proximity_issues list such as may be produced by process 1500 of FIG. 15, DTI symmetry, according to an embodiment.

At step S1602, the process 1600 sets an asymmetry_flags variable to an empty list.

At step S1604, the process 1600 iterates through each entry (i.e., each issue) in the proximity_issues list.

At step S1606, the process 1600 assigns a DTI of the issue currently being processed to the variable dti.

At step S1608, the process 1600 calculates the x and y spans for the DTI. The x span of the DTI may correspond to the absolute value for a difference between a first x coordinate of the DTI and a second x coordinate of the DTI. The y span of the DTI may correspond to the absolute value for a difference between a first y coordinate of the DTI and a second y coordinate of the DTI. The first x and y coordinates may correspond to a first corner of the DTI, and the second x and y coordinates may correspond to a second corner of the DTI that is diagonally opposite the first corner.

At step S1610, the process 1600 determines whether the x span of the DTI is equal to the y span of the DTI. If so, the process 1600 proceeds to the next iteration of the loop of step S1604. If not, the process 1600 proceeds to step S1612.

At step S1612, the process 1600 appends an entry to the asymmetry_flags list, the entry including an indication of the device corresponding to the issue currently being processed, an indication of the DTI currently being processed, and an indication that asymmetry was detected.

At step S1614, when the loop of step S1604 has performed all its iterations, the process 1600 outputs the asymmetry_flags list.

FIG. 17 illustrates a process 1700 for grouping devices by wells, according to an embodiment.

At step S1702, the process 1700 sets a wells variable to an empty dictionary.

At step S1704, the process 1700 iterates through all objects in a layout_objects list.

At step S1706, the process 1700 checks whether the current object is a device. If so, the process 1700 proceeds to step S1708; otherwise the process 1700 proceeds to the next iteration of the loop of step S1704.

At step S1708, the process 1700 assigns the well entry of the current object, indicating which well that object is in, to the well variable.

At step S1710, the process 1700 determines whether the well of the current object is in the wells dictionary. If it is, the process 1700 proceeds to step S1714; otherwise the process 1700 proceeds to step S1712.

At step S1712, the process 1700 creates a new entry in the wells dictionary. The new entry corresponds to the well of the current object and includes an indication of the voltage domain of the current object and an empty list of devices.

At step S1714, the process 1700 appends the current object to the list of devices in the entry in the wells dictionary corresponding to the well of the current object.

At step S1716, when the loop of step S1704 has performed all its iterations, the process 1700 outputs the wells dictionary.

FIG. 18 illustrates a process 1800 for checking well domain consistency of an integrated circuit design, according to an embodiment. The process 1800 may use a well_groups input based on the output of the process 1700 of FIG. 17.

At step S1802, the process 1800 sets a domain_consistancy_issues variable to an empty list.

At step S1804, the process 1800 iterates through all entries in the well_groups variable. Each entry may comprise an indication of a well and data, wherein the data includes a voltage of the well. The well indication of the currently-iterated entry of step S1804 is assigned to a well1 variable and the data of the currently-iterated entry of step S1804 is assigned to a data1 variable.

At step S1806, the process 1800 again iterates through all entries in the well_groups variable. The well indication of the currently-iterated entry of step S1806 is assigned to a well2 variable and the data of the currently-iterated entry of step S1806 is assigned to a data2 variable.

At step S1808, the process 1800 determines whether well2 indicates a different well that well1, and if so whether the voltage of the well indicated by data2 (i.e., the voltage of the well2) is the same as the voltage indicated by data1 (i.e., the voltage of the well1). If so, the process 1800 proceeds to step S1810; otherwise the process 1800 proceeds to the next iteration of the loop of step S1806.

At step S1810, the process 1800 appends an entry comprising an indication of well1, an indication of well2, and the voltage of the two wells to the domain_consistancy_issues list.

At step S1812, when the loop of steps S1804 and S1806 have performed all their iterations, the process 1800 outputs the domain_consistancy_issues list.

FIG. 19 illustrates a process 1900 for creating, based, for example, on the domain_consistancy_issues list output by the process 1800 of FIG. 18, a list of well domain merging opportunities for an integrated circuit design, according to an embodiment.

At step S1902, the process 1900 sets a merging_opportunites variable to an empty list.

At step S1904, the process 1900 iterates through all issues in the domain_consistancy_issues list.

At step S1906, the process 1900 appends an entry comprising the target well, source well and voltage of the currently-processed issue to the merging_opportunites list.

At step S1908, when the loop of step S1904 has performed all its iterations, the process 1900 outputs the domain_consistancy_issues list.

FIG. 20 illustrates a process 2000 for identifying DTI-sensitive devices, according to an embodiment.

At step S2002, the process 2000 sets a sensitive_devices variable to an empty list.

At step S2004, the process 2000 iterates over pairs of transistor entries (dev1 and dev2) from a netlist.

At step S2006, the process 2000 determines whether the gates of dev1 and dev2 are commonly connected, whether the sources of dev1 and dev2 are commonly connected, whether the drains of dev1 and dev2 are not commonly connected, and whether the width-to-length (W/L) ratios of the respective channels of dev1 are the same. When all of the above conditions are true, the process 2000 proceeds to step S2008; otherwise, the process 2000 proceeds to step S2010.

At step S2008, the process 2000 creates an entry including the name of dev1, the name of dev2, an indication that they are of the type “differential pair,” and appends the entry to the sensitive_devices list. The entry may also include properties of the dev1/dev2 pair, such as that they have a shared source along with an indication of that source and that they have a common gate along with an indication of that gate.

At step S2010, the process 2000 determines whether the gates of dev1 and dev2 are commonly connected, whether the sources of dev1 and dev2 are commonly connected, whether the drains of dev1 and dev2 are not commonly connected, and whether the width-to-length (W/L) ratios of the respective channels of dev1 are the same. When all of the above conditions are true, the process 2000 determines that the transistors are a differential pair and proceeds to step S2008; otherwise, the process 2000 proceeds to step S2010.

At step S2012, the process 2000 creates an entry including the name of dev1, the name of dev2, an indication that they are of the type “current mirror,” and appends the entry to the sensitive_devices list. The entry may also include properties of the dev1/dev2 pair, such as an indication of which device is the input device and an indication of which device is the output device.

At step S2014, when the loop of step S2004 has performed all its iterations, the process 2000 outputs the sensitive_devices list of DTI-sensitive devices.

Although the invention has been be described with reference to DTIs, wells, and DTI-sensitive devices, embodiments are not limited thereto. A person of skill in the related arts would understand how to adapt the disclosure to eliminate other kinds of redundant interposed separation/isolation structures or other devices having performance sensitive to the proximity or asymmetric disposition of nearby separation/isolation structures.

Embodiments may lower the cost of producing integrated circuits by eliminating unnecessary structures that waste area on the die. Embodiments may also improve the performance of integrated circuits by detecting and eliminating proximity effects of isolation/separation structures..

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting.

1. A method for performing semiconductor design performed by a computer, the method comprising:
parsing layout data to produce parsed layout data;
parsing netlist data to produce parsed netlist data;
determining, using the parsed layout data, a list of Deep Trench Isolation (DTI) objects;
determining, using the parsed layout data, boundaries of voltage domains;
grouping devices in the parsed layout data according to the respective voltage domains of the devices to produce one or more voltage domain entries; and
for each of the one or more voltage domain entries:
extracting a first list of devices from the parsed layout data, the first list of devices corresponding to devices in parsed layout data that are in the voltage domain of the voltage domain entry,
extracting a second list of devices from the parsed netlist data, the second list of devices corresponding to devices in parsed netlist data that are in the voltage domain of the voltage domain entry,
comparing the first list of devices to the second list of devices, and
determining that a compaction opportunity exists when a device exists in the first list of devices that does not exist in the second list of devices, a device exists in the second list of devices that does not exist in the first list of devices, or both.

2. The method of claim 1, further comprising:
when the compaction opportunity exists, identify a DTI disposed between two devices in one of the one or more voltage domain entries as an unnecessary DTI.

3. The method of claim 2, further comprising:
when the compaction opportunity exists, produce, using the layout data, revised layout data not having the unnecessary DTI.

4. The method of claim 1, further comprising:
determining, using the parsed layout data, a list of DTI-sensitive devices;
determining, using the list of DTI-sensitive devices, a proximity issues list comprising a list of proximity pairs, each pair including a DTI and a DTI-sensitive device that are close enough to potentially be an issue;
determining, using the list of proximity pairs, an asymmetry flag list having entries respectively indicating a DTI-sensitive devices around which nearby DTIs are asymmetrically arranged; and
output the asymmetry flag list.

5. The method of claim 4, wherein determining, using the list of proximity pairs, the asymmetry flag list comprises:
calculating an x span for the DTI of a proximity pair of the list of proximity pairs, the x span corresponding to a difference between a first x coordinate of the DTI and a second x coordinate of the DTI,
calculating an y span for the DTI of the proximity pair, the y span corresponding to a difference between a first y coordinate of the DTI and a second y coordinate of the DTI,
determining whether the x span is not equal to the y span, and
in response to determining that the x span is not equal to the y span, appending an entry comprised of the device of the proximity pair and the DTI of the proximity pair to the asymmetry flag list.

6. The method of claim 1, further comprising:
produce a list of group, using the parsed layout data, a dictionary including a plurality of entries, each entry including an indication of a respective well, an indication of a voltage corresponding to that well, and a list of devices in that well;
produce, using the dictionary, a domain consistency issue list by performing a well and domain connectivity and consistency check, each entry in the domain consistency issue list comprising an identifier of a first corresponding well, an identifier of a second corresponding well different from the first corresponding well, and a voltage corresponding to both the first and second corresponding wells;
produce, using the domain consistency issue list, a list of opportunities to merge wells.

7. The method of claim 6, further comprising:
produce, using the layout data and the list of opportunities to merge wells, revised layout data in which one or more pairs of wells identified in the list of opportunities to merge wells are merged into a single well.

8. The method of claim 1, wherein determining, using the parsed layout data, the boundaries of voltage domains comprises:
determining whether an object in the parsed layout data is a device; and
in response to determining that the object is the device:
determining a voltage of the object,
when an entry corresponding to the voltage of the object is not present in a representation of voltage domains, creating the entry corresponding to the voltage of the object in the representation of voltage domains, and
appending the object to a list in the entry corresponding to the voltage of the object.

9. The method of claim 1, wherein grouping devices in the parsed layout data according to the respective voltage domains of the devices to produce one or more voltage domain entries comprises:
for each object in the parsed layout data:
when the object is a device:
determine, from among the one or more voltage domain entries, an entry corresponding to a supply voltage of the object, and
append the object to the entry.

10. The method of claim 1, wherein determining that the compaction opportunity exists comprises:
determining whether a voltage domain includes more than one device; and
in response to determining that the voltage domain include more than one device, appending an entry including a first device included in the voltage domain and a second device included in the voltage domain to a compaction opportunities list, where the second device is different from the first device.

11. A non-transient computer-readable medium (CRM) comprising computer programming instructions which, when executed by a computer, cause the computer to perform steps of a process for semiconductor design, the steps comprising:
parsing layout data to produce parsed layout data;
parsing netlist data to produce parsed netlist data;
determining, using the parsed layout data, a list of Deep Trench Isolation (DTI) objects;
determining, using the parsed layout data, boundaries of voltage domains;
grouping devices in the parsed layout data according to the respective voltage domains of the devices to produce one or more voltage domain entries; and
for each of the one or more voltage domain entries:
extracting a first list of devices from the parsed layout data, the first list of devices corresponding to devices in parsed layout data that are in the voltage domain of the voltage domain entry,
extracting a second list of devices from the parsed netlist data, the second list of devices corresponding to devices in parsed netlist data that are in the voltage domain of the voltage domain entry,
comparing the first list of devices to the second list of devices, and
determining that a compaction opportunity exists when a device exists in the first list of devices that does not exist in the second list of devices, a device exists in the second list of devices that does not exist in the first list of devices, or both.

12. The non-transient CRM of claim 11, wherein the steps further comprise:
when the compaction opportunity exists, identify a DTI disposed between two devices in one of the one or more voltage domain entries as an unnecessary DTI.

13. The non-transient CRM of claim 11, wherein the steps further comprise:
when the compaction opportunity exists, produce, using the layout data, revised layout data not having the unnecessary DTI.

14. The non-transient CRM of claim 11, wherein the steps further comprise:
determining, using the parsed layout data, a list of DTI-sensitive devices;
determining, using the list of DTI-sensitive devices, a proximity issues list comprising a list of proximity pairs, each pair including a DTI and a DTI-sensitive device that are close enough to potentially be an issue;
determining, using the list of proximity pairs, an asymmetry flag list having entries respectively indicating a DTI-sensitive devices around which nearby DTIs are asymmetrically arranged; and
output the asymmetry flag list.

15. The non-transient CRM of claim 14, wherein determining, using the list of proximity pairs, the asymmetry flag list comprises:
calculating an x span for the DTI of a proximity pair of the list of proximity pairs, the x span corresponding to a difference between a first x coordinate of the DTI and a second x coordinate of the DTI,
calculating an y span for the DTI of the proximity pair, the y span corresponding to a difference between a first y coordinate of the DTI and a second y coordinate of the DTI,
determining whether the x span is not equal to the y span, and
in response to determining that the x span is not equal to the y span, appending an entry comprised of the device of the proximity pair and the DTI of the proximity pair to the asymmetry flag list.

16. The non-transient CRM of claim 11, wherein the steps further comprise:
produce a list of group, using the parsed layout data, a dictionary including a plurality of entries, each entry including an indication of a respective well, an indication of a voltage corresponding to that well, and a list of devices in that well;
produce, using the dictionary, a domain consistency issue list by performing a well and domain connectivity and consistency check, each entry in the domain consistency issue list comprising an identifier of a first corresponding well, an identifier of a second corresponding well different from the first corresponding well, and a voltage corresponding to both the first and second corresponding wells;
produce, using the domain consistency issue list, a list of opportunities to merge wells.

17. The non-transient CRM of claim 16, wherein the steps further comprise:
produce, using the layout data and the list of opportunities to merge wells, revised layout data in which one or more pairs of wells identified in the list of opportunities to merge wells are merged into a single well.

18. The non-transient CRM of claim 11, wherein determining, using the parsed layout data, the boundaries of voltage domains comprises:
determining whether an object in the parsed layout data is a device; and
in response to determining that the object is the device:
determining a voltage of the object;
when an entry corresponding to the voltage of the object is not present in a representation of voltage domains, creating the entry corresponding to the voltage of the object in the representation of voltage domains; and
appending the object to a list in the entry corresponding to the voltage of the object.

19. The non-transient CRM of claim 11, wherein grouping devices in the parsed layout data according to the respective voltage domains of the devices to produce one or more voltage domain entries comprises:
for each object in the parsed layout data:
when the object is a device:
determine, from among the one or more voltage domain entries, an entry corresponding to a supply voltage of the object, and
append the object to the entry.

20. The non-transient CRM of claim 11, wherein determining that the compaction opportunity exists comprises:
determining whether a voltage domain includes more than one device; and
in response to determining that the voltage domain include more than one device, appending an entry including a first device included in the voltage domain and a second device included in the voltage domain to a compaction opportunities list, where the second device is different from the first device.
